(19) United States
(12) Patent Application Publication
(10) Pub. No.: US 2026/0005028 A1
(43) Pub. Date: Jan. 1, 2026

(54) PULSING DEPOSITION USING FAST RESPONSE MFC

(71) Applicant: Applied Materials, Inc., Santa Clara, CA (US)

(72) Inventors: Zheyuan Chen, Sunnyvale, CA (US); Jianxin Lei, Saratoga, CA (US); Allyson N. Vu, San Jose, CA (US)

(73) Assignee: Applied Materials, Inc., Santa Clara, CA (US)

(21) Appl. No.: 18/758,301

(22) Filed: Jun. 28, 2024

(51) Int. Cl. H01L 21/285; C23C 14/06; C23C 14/34; C23C 14/54; H01L 29/49

(52) U.S. Cl. CPC H01L 21/28568; C23C 14/0641; C23C 14/3414; C23C 14/54; H10D 64/667

(57) ABSTRACT

Methods for forming work function layers (e.g., titanium nitride work function layers) for transistors are described. The methods energizing a process gas disposed in an inner volume of a processing chamber to create a plasma, and pulsing the process gas between a poison regime and a metallic regime using a fast response mass flow controller to deposit the work function layer on the substrate surface.

### TECHNICAL FIELD

Embodiments of the disclosure generally relate to methods of metal nitride films in the manufacture of microelectronic devices. More particularly, embodiments of the disclosure are directed to methods for depositing titanium nitride films with improved atomic ratio uniformity.

### BACKGROUND

The electronic device industry and the semiconductor industry continue to strive for larger production yields while increasing the uniformity of layers deposited on substrates having increasingly larger surface areas. These same factors in combination with new materials also provide higher integration of circuits per unit area on the substrate.

As the dimensions of electronic devices continue to shrink, tolerances for individual layer non-uniformity decreases. During formation of transistors, titanium nitride (TiN) layers are often used as a work function layer, which is used to control/affect the threshold voltage (Vₜ) of the device. Titanium nitride films are frequently deposited using physical vapor deposition (PVD) using a titanium target with nitrogen (N₂) as the process gas. However, the threshold voltage (Vₜ) across the wafer, i.e. the center-edge threshold voltage (Vₜ), can vary due to non-uniformity of the titanium-nitrogen atomic ratio across the substrate surface. The inventors have found that the variations in threshold voltage (Vₜ) are correlated with the nitrogen ratio uniformity in the titanium nitride film.

Current mass flow controllers (MFCs) have response delays greater than 0.25 seconds, and even up to 1 second, depending on the flow rate. For a constant flow rate process, the response delay is not an issue. However, for pulsed flow processes, this response delay is often a substantial portion of the pulse width, resulting in a significant delay. For example, in a process with a two second pulse width, the response delay of the MFC can be up to 50% of the pulse width resulting in a mis-match of the flow profile with the programmed pulsing pattern. Additionally, the ON delay and OFF delay of conventional MFCs is are not necessarily the same for any given MFC, making chamber matching and control uniformity difficult to achieve.

Accordingly, there is a need for apparatus and methods for depositing material layers that improve deposition uniformity in physical vapor deposition processes.

### SUMMARY

One or more embodiments of the disclosure are directed to a method of forming a work function layer for a transistor. The method comprises energizing a process gas disposed in an inner volume of a processing chamber to create a plasma. The processing chamber has a sputtering target and the plasma causes atoms to eject from the sputtering target toward a substrate surface. The process gas is pulsed between a poison regime and a metallic regime using a fast response mass flow controller to deposit the work function layer on the substrate surface. The fast response mass flow controller has an ON response delay and an OFF response delay independently less than or equal to 0.25 seconds at a flow rate in the range of 5 sccm to 100 sccm.

Additional embodiments of the disclosure are directed to a method of forming a titanium nitride work function layer for a transistor. The method comprises flowing a process gas comprising argon and nitrogen into an inner volume of a processing chamber comprising a titanium target and a substrate with a substrate surface. The process gas is energized to create a plasma in the inner volume to cause titanium atoms to eject from the sputtering target toward the substrate surface. The process gas is pulsed between a poison regime and a metallic regime using a fast response mass flow controller to deposit the titanium nitride work function layer on the substrate surface. The fast response mass flow controller has an ON response delay and an OFF response delay independently less than or equal to 0.15 seconds at a flow rate in the range of 5 sccm to 100 sccm. The metallic regime has a nitrogen flow rate in the range of 20 sccm to 30 sccm, and the poison regime has a nitrogen flow rate in the range of 25 sccm to 35 sccm and is greater than the nitrogen flow rate of the metallic regime.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 depicts a schematic side view of a processing chamber in accordance with some embodiments of the present disclosure;

FIG. 2 depicts a schematic cross-sectional view of a process kit in accordance with some embodiments of the present disclosure;

FIG. 3 is a flowchart of a method for forming a work function layer for a transistor in accordance with some embodiments of the present disclosure; and

FIG. 4 is a graph of the flow rate of process gases as a function of time according to one or more embodiment.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

The Figures are shaded to help identify individual components. The shading is for illustrative purposes only and no particular materials of construction are intended and the scope of the disclosure is not limited to any particular materials of construction absent a clear indication.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

The term “about” as used herein means approximately or nearly and in the context of a numerical value or range set forth means a variation of ±15%, or less, of the numerical value. For example, a value differing by ±14%, ±10%, ±5%, ±2%, or ±1%, would satisfy the definition of about.

Spatially relative terms, such as “beneath,” “below,” “lower,” “above,” “upper” and the like, may be used herein for ease of description to describe one element's relationship to another element(s) or feature(s) as illustrated in the Figures. It will be understood that the spatially relative terms are intended to encompass different orientations of the microelectronic device in use or operation in addition to the orientation depicted in the Figures. For example, if the microelectronic device in the Figures is turned over, elements described as “below” or “beneath” other elements would then be oriented “above” the other elements. Thus, the exemplary term “below” may encompass both an orientation of above and below. The microelectronic device may be otherwise oriented (rotated 90 degrees or at other orientations) and the spatially relative descriptors used herein interpreted accordingly.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “certain embodiments,” “one or more embodiments,” “some embodiments,” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in some embodiments,” “in one embodiment,” or “in an embodiment” in various places throughout this specification are not necessarily referring to the same embodiment of the disclosure. In one or more embodiments, the particular features, structures, materials, or characteristics are combined in any suitable manner.

As used in this specification and the appended claims, the term “substrate” and “wafer” are used interchangeably, both referring to a surface, or portion of a surface, upon which a process acts. It will also be understood by those skilled in the art that reference to a substrate can also refer to only a portion of the substrate, unless the context clearly indicates otherwise. Additionally, reference to “depositing on” or “forming on” a substrate can mean both a bare substrate and a substrate with one or more films or features deposited or formed thereon.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, silicon nitride, doped silicon, germanium, gallium arsenide, glass, sapphire, and any other materials such as metals, metal nitrides, metal alloys, and other conductive materials, depending on the application. Substrates include, without limitation, semiconductor wafers. In some embodiments, the semiconductor substrate comprises one or more of doped or undoped crystalline silicon (Si), doped or undoped crystalline silicon germanium (SiGe), doped or undoped amorphous silicon (Si), or doped or undoped amorphous silicon germanium (SiGe). Substrates may be exposed to a pretreatment process to polish, etch, reduce, oxidize, hydroxylate (or otherwise generate or graft target chemical moieties to impart chemical functionality), anneal and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus, for example, where a film/layer or partial film/layer has been deposited onto a substrate surface, the exposed surface of the newly deposited film/layer becomes the substrate surface.

The term “on” indicates that there is direct contact between elements. The term “directly on” indicates that there is direct contact between elements with no intervening elements.

As used herein, the term “in situ” refers to processes that are all performed in the same processing chamber or within different processing chambers that are connected as part of an integrated processing system, such that each of the processes are performed without an intervening vacuum break. As used herein, the term “ex situ” refers to processes that are performed in at least two different processing chambers such that one or more of the processes are performed with an intervening vacuum break. In some embodiments, processes are performed without breaking vacuum or without exposure to ambient air.

As used herein, the terms “precursor,” “reactant,” “reactive gas,” “reactive species,” and the like are used interchangeably to refer to any gaseous species that can react with the substrate surface.

Sputtering is a physical vapor deposition (PVD) process in which high-energy ions impact and erode a solid target and deposit the target material on the surface of a substrate, such as a semiconductor substrate. In semiconductor fabrication, the sputtering process is usually accomplished within a semiconductor fabrication chamber also known as a PVD processing chamber or a sputtering chamber. Sputtering has long been used for the deposition of metals and related materials in the fabrication of semiconductor integrated circuits.

Typically, the sputtering chamber comprises an enclosure wall that encloses a process zone into which a process gas is introduced, a gas energizer to energize the process gas, and an exhaust port to exhaust and control the pressure of the process gas in the chamber. The chamber is used to sputter deposit a material from a sputtering target onto the semiconductor substrate. In the sputtering processes, the sputtering target is bombarded by energetic ions, such as a plasma, causing material to be knocked off the target and deposited as a film on the semiconductor substrate.

A typical semiconductor fabrication chamber has a target assembly including disc-shaped target of solid metal or other material supported by a backing plate that holds the target. To promote uniform deposition, the PVD chamber may have an annular concentric metallic ring, which is often called a shield, circumferentially surrounding the disc-shaped target.

Plasma sputtering may be accomplished using either DC sputtering or RF sputtering. Plasma sputtering typically includes a magnetron positioned at the back of a sputtering target including two magnets of opposing poles magnetically coupled at their back through a magnetic yoke to project a magnetic field into the processing space to increase the density of the plasma and enhance the sputtering rate from a front face of the target. Magnets used in the magnetron are typically closed loop for DC sputtering and open loop for RF sputtering.

As used herein, the term “purging” includes any suitable purge process that removes unreacted precursor, reaction products and by-products from the process region. The suitable purge process includes moving the substrate through a gas curtain to a portion or sector of the processing region that contains none or substantially none of the reactant. In one or more embodiments, purging the processing chamber comprises applying a vacuum. In some embodiments, purging the processing region comprises flowing a purge gas over the substrate. In some embodiments, the purge process comprises flowing an inert gas. In one or more embodiments, the purge gas is selected from one or more of nitrogen (N₂), helium (He), and argon (Ar). In some embodiments, the first reactive species is purged from the reaction chamber for a time duration in a range of from 0.1 seconds to 30 seconds, from 0.1 seconds to 10 seconds, from 0.1 seconds to 5 seconds, from 0.5 seconds to 30 seconds, from 0.5 seconds to 10 seconds, from 0.5 seconds to 5 seconds, from 1 seconds to 30 seconds, from 1 seconds to 10 seconds, from 1 seconds to 5 seconds, from 5 seconds to 30 seconds, from 5 seconds to 10 seconds or from 10 seconds to 30 seconds before exposing the substrate to the second reactive species.

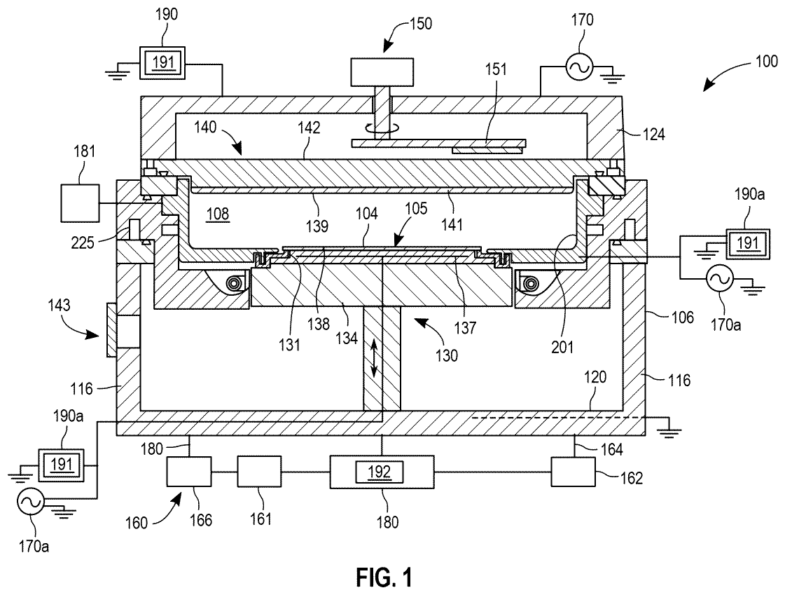

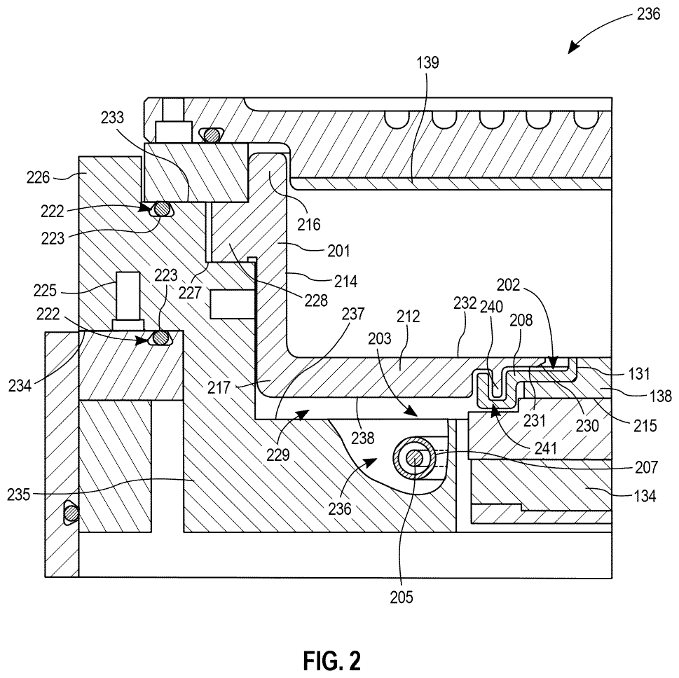

FIG. 1 illustrates a schematic representation of a physical vapor deposition (PVD) processing chamber 100 that can be used with one or more embodiment of the disclosure. FIG. 2 illustrates an expanded view of a portion of the physical vapor deposition (PVD) processing chamber 100 of FIG. 1.

The processing chamber 100 comprises chamber walls 106 that enclose an inner volume 108 (also referred to as a process volume or process cavity). The chamber walls 106 include sidewalls 116, a bottom wall 120, and a ceiling or lid 124. The processing chamber 100 can be a standalone chamber or a part of a multi-chamber platform (not shown) having a cluster of interconnected chambers connected by a substrate transfer mechanism that transfers substrates 104 between the various chambers. The processing chamber 100 may be a PVD chamber capable of sputter depositing material onto a substrate 104. Non-limiting examples of suitable materials for sputter deposition include one or more of carbon, carbon nitride, aluminum, copper, tantalum, tantalum nitride, titanium, titanium nitride, tungsten, tungsten nitride, or the like.

The processing chamber 100 comprises a substrate support 130 which comprises a pedestal 134 to support the substrate 104. The substrate support surface 138 of the pedestal 134 receives and supports the substrate 104 during processing. The pedestal 134 may include an electrostatic chuck or a heater (such as an electrical resistance heater, heat exchanger, or other suitable heating device).

The substrate 104 can be introduced into the processing chamber 100 through a substrate loading inlet 143 (also referred to as a slit valve) in the sidewall 116 of the processing chamber 100 and placed onto the substrate support 130. The substrate support 130 can be lifted or lowered by a support lift mechanism, and a lift finger assembly can be used to lift and lower the substrate 104 onto the substrate support 130 during placement of the substrate 104 on the substrate support 130 by a robot arm.

The pedestal 134 is biasable and can be maintained at an electrically floating potential or grounded during plasma operation. For example, in some embodiments the pedestal 134 may be biased to a given potential such that during a cleaning process of a process kit an RF power source 170 can be used to ignite one or more gases (e.g., a deposition gas or cleaning gas) to create a plasma including ions and radicals that can used to react with one or more materials.

The pedestal 134 has a substrate support surface 138 having a plane substantially parallel to a sputtering surface 139 of a sputtering target 140. The sputtering target 140 comprises a sputtering plate 141 mounted to a backing plate 142, which can be thermally conductive, using one or more suitable mounting devices, e.g., a solder bond. The sputtering plate 141 comprises a material to be sputtered onto the substrate 104. The backing plate 142 is made from a metal, such as, for example, stainless steel, aluminum, copper-chromium or copper-zinc. The backing plate 142 can be made from a material having a thermal conductivity that is sufficiently high to dissipate the heat generated in the sputtering target 140, which is formed in both the sputtering plate 141 and the backing plate 142. The heat is generated from the eddy currents that arise in the sputtering plate 141 and the backing plate 142 and also from the bombardment of energetic ions from the plasma onto the sputtering surface 139 of the sputtering target 140. The backing plate 142 allows dissipation of the heat generated in the sputtering target 140 to the surrounding structures or to a heat exchanger which may be mounted behind the backing plate 142 or disposed within the backing plate 142. For example, the backing plate 142 can comprise channels (not shown) to circulate a heat transfer fluid therein. A suitably high thermal conductivity of the backing plate 142 is at least about 200 W/mK, for example, from about 220 to about 400 W/mK. Such a thermal conductivity level allows the sputtering target 140 to be operated for longer process time periods by dissipating the heat generated in the sputtering target 140 more efficiently, and also allows for relatively rapid cooling of the sputtering plate 141.

Alternatively, or additionally, in combination with a backing plate 142 made of a material having a high thermal conductivity and low resistivity and the channels provided thereon, the backing plate 142 may comprise a backside surface having one or more grooves (not shown). For example, a backing plate 142 could have a groove, such as annular groove, or a ridge, for cooling a backside of the sputtering target 140. The grooves and ridges can also have other patterns, for example, rectangular grid pattern, spiral patterns, chicken feet patterns, or simply straight lines running across the backside surface. The grooves can be used to facilitate dissipating heat from the backing plate.

In some embodiments, the processing chamber 100 may include a magnetic field generator 150 (also referred to as a magnetron) to shape a magnetic field about the sputtering target 140 to improve sputtering of the sputtering target 140. The capacitively generated plasma may be enhanced by the magnetic field generator 150 in which, for example, a plurality of magnets 151 (e.g., permanent magnet or electromagnetic coils) may provide a magnetic field in the processing chamber 100 that has a rotating magnetic field having a rotational axis that is perpendicular to the plane of the substrate 104. The processing chamber 100 may, in addition or alternatively, comprise a magnetic field generator 150 that generates a magnetic field near the sputtering target 140 of the processing chamber 100 to increase an ion density in a high-density plasma region adjacent to the sputtering target 140 to improve the sputtering of the target material.

A sputtering gas is introduced into the processing chamber 100 through a gas delivery system 160, which provides gas from a gas supply 161 via conduits 163 having gas flow control valves, such as a mass flow controller 166, to pass a set flow rate of the gas therethrough. The process gas may comprise a non-reactive gas, such as argon or xenon, which is capable of energetically impinging upon and sputtering material from the sputtering target 140. The process gas may also comprise a reactive gas, such as one or more of oxygen (O₂), an oxygen-containing gas, nitrogen (N₂) and a nitrogen-containing gas, that can react with the sputtered material to form a layer on the substrate 104. The gas is then energized by an RF power source 170 to form or create a plasma to sputter the sputtering target 140. For example, the process gases become ionized by high energy electrons and the ionized gases are attracted to the sputtering material, which is biased at a negative voltage (e.g., −300 to −1500 volts). The energy imparted to an ionized gas (e.g., now positively charged gas atoms) by the electric potential of the cathode causes sputtering. In some embodiments, the reactive gases can directly react with the sputtering target 140 to create compounds and then be subsequently sputtered from the sputtering target 140. For example, the cathode can be energized by both the DC power source 190 and the RF power source. In some embodiments, the DC power source 190 can be configured to provide pulsed DC to power the cathode.

Spent process gas and byproducts are exhausted from the processing chamber 100 through an exhaust 162. The exhaust 162 comprises an exhaust port (not shown) that receives spent process gas and passes the spent gas to an exhaust conduit 164 having a throttle valve to control the pressure of the gas in the processing chamber 100. The exhaust conduit 164 is connected to one or more exhaust pumps (not shown).

In addition, the gas delivery system 160 is configured to introduce one or more of the gases (e.g., depending on the material used for the sputtering target 140), which can be energized to create an active cleaning gas (e.g., ionized plasma or radicals), into the inner volume 108 of the processing chamber 100 for performing a cleaning process of a shield of a process kit, which will be described in greater detail below. Alternatively or additionally, the gas delivery system 160 can be coupled to a remote plasma source (RPS) (not shown) that is configured to provide radicals (or plasma depending on the configuration of the RPS) into the inner volume 108 of the processing chamber 100.

The sputtering target 140 is connected to one or both of a DC power source 190 and/or the RF power source 170. The DC power source 190 can apply a bias voltage to the sputtering target 140 relative to a shield of the process kit, which may be electrically floating during a sputtering process and/or the cleaning process. The DC power source 190, or a different DC power source 190a, can also be used to apply a bias voltage to a cover ring section or a heater of an adapter section of a process kit, e.g., when performing a cleaning process of a shield.

While the DC power source 190 supplies power to the sputtering target 140 and other chamber components connected to the DC power source 190, the RF power source 170 energizes the sputtering gas to form a plasma of the sputtering gas. The plasma formed impinges upon and bombards the sputtering surface 139 of the sputtering target 140 to sputter material off the sputtering surface 139 onto the substrate 104. In some embodiments, RF energy supplied by the RF power source 170 may range in frequency from about 2 MHz to about 60 MHZ, or, for example, non-limiting frequencies such as 2 MHZ, 13.56 MHZ, 27.12 MHz, or 60 MHz can be used. In some embodiments, a plurality of RF power sources may be provided (i.e., two or more) to provide RF energy in a plurality of the above frequencies. An additional RF power source can also be used to supply a bias voltage to the pedestal 134 and/or a cover ring section e.g., when performing a cleaning process of the area on and around a process kit. For example, in some embodiments an additional RF power source 170 a can be used to energize a biasable electrode 137 that can be embedded in the pedestal 134 (or the substrate support surface 138 of the substrate support 130). The biasable electrode can be used to supply power to a shield and/or the substrate support 130. Moreover, in some embodiments, the RF power source 170 can be configured to energize the biasable electrode 137. For example, one or more additional components e.g., a switching circuit can be provided to switch the electrical path from the cover or lid 124 to the biasable electrode 137.

An RF filter 191 can be connected between the DC power source 190 (or the DC power source 190 a) and the RF power source 170 (or the RF power source 170a). For example, in at least some embodiments, the RF filter can be a component of the circuitry of the DC power source 190 to block RF signals from entering the DC circuitry of the DC power source 190 when the RF power source 170 is running, e.g., when performing a cleaning process.

Various components of the processing chamber 100 may be controlled by a controller 180 (processor). The controller 180 comprises program code (e.g., stored in a non-transitory computer readable storage medium (memory)) having instructions to operate the components to process the substrate 104. For example, the controller 180 can comprise program code that includes substrate positioning instruction sets to operate the substrate support 130 and substrate transfer mechanism; temperature control of one or more heating components (e.g., a lamp, radiative heating, and/or embedded resistive heaters) of a heater; cleaning process instruction sets to an area on and around a process kit; power control of a microwave power source 181; gas flow control instruction sets to operate gas flow control valves to set a flow of sputtering gas to the processing chamber 100; gas pressure control instruction sets to operate the exhaust throttle valve to maintain a pressure (e.g., about 120 sccm) in the processing chamber 100; gas energizer control instruction sets to operate the RF power source 170 to set a gas energizing power level; temperature control instruction sets to control a temperature control system in the substrate support 130 or a heat transfer medium supply to control a flowrate of the heat transfer medium to the annular heat transfer channel; and process monitoring instruction sets to monitor the process in the processing chamber 100, e.g., monitoring/adjusting an active capacitor tuner (ACT) 192. For example, in at least some embodiments, the ACT 192 can be used to tune the pedestal 134 during a cleaning process.

FIG. 2 depicts a schematic cross-sectional view of a process kit 200 in accordance with some embodiments of the present disclosure. The process kit 200 comprises various components including an adapter section 226 and a shield 201 which can be easily removed from the processing chamber 100, for example, to replace or repair eroded components, or to adapt the processing chamber 100 for other processes. Additionally, unlike conventional process kits, which need to be removed to clean sputtering deposits off the component surfaces (e.g., the shield 201), the inventors have designed the process kit 200 for in situ cleaning to remove sputtered deposits of material on the of the shield 201.

The shield 201 includes a cylindrical body 214 having a diameter sized to encircle the sputtering surface 139 of the sputtering target 140 and the substrate support 130 (e.g., a diameter larger than the sputtering surface 139 and larger than the support surface of the substrate support 130). The cylindrical body 214 has an upper portion 216 configured to surround the outer edge of the sputtering surface 139 of the sputtering target 140 when installed in the chamber. The shield 201 further includes a lower portion 217 configured to surround the substrate support surface 138 of the substrate support 130 when installed in the chamber. The lower portion 217 includes a cover ring section 212 for placement about a peripheral wall 131 of the substrate support 130. The cover ring section 212 encircles and at least partially covers a deposition ring 208 disposed about the substrate support 130 to receive, and thus, shadow the deposition ring 208 from the bulk of the sputtering deposits. As noted above, in some embodiments the cover ring section 212 can be biased using the DC power source 190a and/or the RF power source 170a, for example, when the area on and around the process kit 200 needs to be cleaned. In some embodiments, the RF power source 170 or the DC power source 190 can also be configured to bias the cover ring section 212.

The deposition ring 208 is disposed below the cover ring section 212. A bottom surface of the cover ring section 212 interfaces with the deposition ring 208 to form a tortuous path 202 and the cover ring section 212 extends radially inward from the lower portion 217 of the cylindrical body 214, as shown in FIG. 2. In some embodiments, the cover ring section 212 interfaces with but does not contact the deposition ring 208 such that the tortuous path 202 is a gap disposed between the cover ring section 212 and the deposition ring 208. For example, the bottom surface of the cover ring section 212 may include an annular leg 240 that extends into an annular trench 241 formed in the deposition ring 208. The tortuous path 202 advantageously limits or prevents plasma leakage to an area outside of the process kit 200. Moreover, the constricted flow path of the tortuous path 202 restricts the build-up of low-energy sputter deposits on the mating surfaces of the deposition ring 208 and cover ring section 212, which would otherwise cause them to stick to one another or to the overhanging edge 206 of the substrate 104. Additionally, in some embodiments, the gas delivery system 160 is in fluid communication with the tortuous path 202 for providing one or more suitable gases (e.g., process gas and/or cleaning gas) into the inner volume 108 of the processing chamber 100.

The deposition ring 208 is at least partially covered by a radially inwardly extending lip 230 of the cover ring section 212. The lip 230 includes a lower surface 231 and an upper surface 232. The deposition ring 208 and cover ring section 212 cooperate with one another to reduce formation of sputter deposits on the peripheral walls 131 of the substrate support 130 and an overhanging edge of the substrate 104. The lip 230 of the cover ring section 212 is spaced apart from the overhanging edge 206 by a horizontal distance that may be between about 0.5 inches and about 1 inch to reduce a disruptive electrical field near the substrate 104 (i.e., an inner diameter of the lip 230 is greater than a given diameter of a substrate to be processed by about 1 inch to about 2 inches).

The deposition ring 208 comprises an annular band 215 that extends about and surrounds a peripheral wall 131 of the substrate support 130 as shown in FIG. 2. The annular band 215 comprises an inner lip 250 which extends transversely from the annular band 215 and is substantially parallel to the peripheral wall 204 of the substrate support 130. The inner lip 250 terminates immediately below the overhanging edge 206 of the substrate 104. The inner lip 250 defines an inner perimeter of the deposition ring 208 which surrounds the periphery of the substrate 104 and substrate support 130 to protect regions of the substrate support 130 that are not covered by the substrate 104 during processing. For example, the inner lip 250 surrounds and at least partially covers the peripheral wall 204 of the substrate support 130 that would otherwise be exposed to the processing environment, to reduce or even entirely preclude deposition of sputtering deposits on the peripheral wall 204. The deposition ring 208 can serve to protect the exposed side surfaces of the substrate support 130 to reduce their erosion by the energized plasma species.

The shield 201 encircles the sputtering surface 139 of the sputtering target 140 that faces the substrate support 130 and the outer periphery of the substrate support 130. The shield 201 covers and shadows the sidewalls 116 of the processing chamber 100 to reduce deposition of sputtering deposits originating from the sputtering surface 139 of the sputtering target 140 onto the components and surfaces behind the shield 201. For example, the shield 201 can protect the surfaces of the substrate support 130, overhanging edge 206 of the substrate 104, sidewalls 116 and bottom wall 120 of the processing chamber 100.

Continuing with reference to FIG. 2, the adapter section 226 extends radially outward adjacent from the upper portion 216. The adapter section 226 includes a sealing surface 233 and a resting surface 234 opposite the sealing surface 233. The sealing surface 233 contains an O-ring groove 222 to receive an O-ring 223 to form a vacuum seal, and the resting surface 234 rests upon (or is supported by) the sidewalls 116 of the processing chamber 100; an O-ring groove 222 and an O-ring 223 can also be provided in the sidewall 116 opposite the resting surface 234.

The adapter section 226 is configured to be supported on walls of the processing chamber 100. More particularly, the adapter section 226 includes an inwardly extending ledge 227 that engages a corresponding outwardly extending ledge 228 adjacent the upper portion 216 for supporting of the shield 201. The adapter section 226 includes a lower portion 235 that extends inwardly toward the pedestal 134 below the cover ring section 212. The lower portion 235 is spaced apart from the cover ring section 212 such that a cavity 229 is formed between the lower portion 235 and the cover ring section 212. The cavity 229 is defined by a top surface 237 of the lower portion 235 and a bottom surface 238 of the cover ring section 212. The distance between the top surface 237 of the lower portion 235 and a bottom surface 238 is such that maximum heat transfer from the heater 203 to the shield 201 can be achieved within a predetermined time during cleaning of the process kit 200. The cavity 229 is in fluid communication with the tortuous path 202 which allows gas, for example, introduced via the gas delivery system 160, to flow into the inner volume 108 of the processing chamber 100 when the area on and around the process kit 200 needs to be cleaned.

The lower portion 235 is configured to house the heater 203. More particularly, an annular groove 236 of suitable configuration is defined within the lower portion 235 and is configured to support one or more suitable heating components including, but not limited to, a lamp, radiative heating, or embedded resistive heaters of the heater 203. In the illustrated embodiment, a radiative annular coil 205, which is surrounded by a lamp envelope 207, e.g., glass, quartz or other suitable material, is shown supported in the annular groove 236. The radiative annular coil 205 can be energized or powered using, for example, the DC power source 190 or the DC power source 190a, which can be controlled by the controller 180, to reach temperatures of about 250° C. to about 300° C. when the area on and around the process kit 200 needs to be cleaned.

The adapter section 226 can also serve as a heat exchanger about the sidewall 116 of the processing chamber 100. Alternatively or additionally an annular heat transfer channel 225 can be disposed in either or both the adapter section 226 or the shield 201 (e.g., the upper portion 216) to flow a heat transfer medium, such as water or the like. The heat transfer medium can be used to cool the adapter section 226 and/or the shield 201, for example, upon completion of the process kit 200 being cleaned, or upon completion of one or more other processes having been performed in the processing chamber 100.

During processing, the inventors have found that the center-to-edge atomic ratio of certain films is non-uniform. For example, in some embodiments, a titanium nitride film is deposited as a work function metal for a transistor. The work function metal is used to control the electrical performance of the transistor and can have a noticeable impact on the overall device performance.

The inventors have found that the conventional mass flow controller 166 does not have a sufficient response time to accurately control the flow of nitrogen (N₂) during a pulsed process. The current mass flow controller has a relatively long delay and inaccurate control over the flow, thus it cannot provide consistent nitrogen pulsing with short pulsing times and lower delays. The inventors have surprisingly found that a mass flow controller with improved response time can more accurately control the flow of nitrogen during a pulsed process to improve the N/Ti atomic ratio uniformity, reducing the center-to-edge non-uniformity. Short pulse times, of about 0.5 seconds and less, can be used to enable a nitrogen pulsing process with improved uniformity. In some embodiments, the nitrogen pulsing deposition includes cycles of pulsing with a relatively high and low nitrogen flow. The first nitrogen pulse in some embodiments uses a slightly higher nitrogen flow to maintain plasma at the “poison regime”. The second pulse uses a lower nitrogen flow for benefiting the N/Ti ratio uniformity. At this flow, the process is in the “metallic regime” or transitioning to the metallic regime and is therefore not stable. When used in conjunction with the first step, the second step with lower nitrogen pulses can sustain the plasma for a certain period of time at the poison regime as well. In some embodiments, the whole deposition process has a lower nitrogen flow compared to current non-pulsing processes.

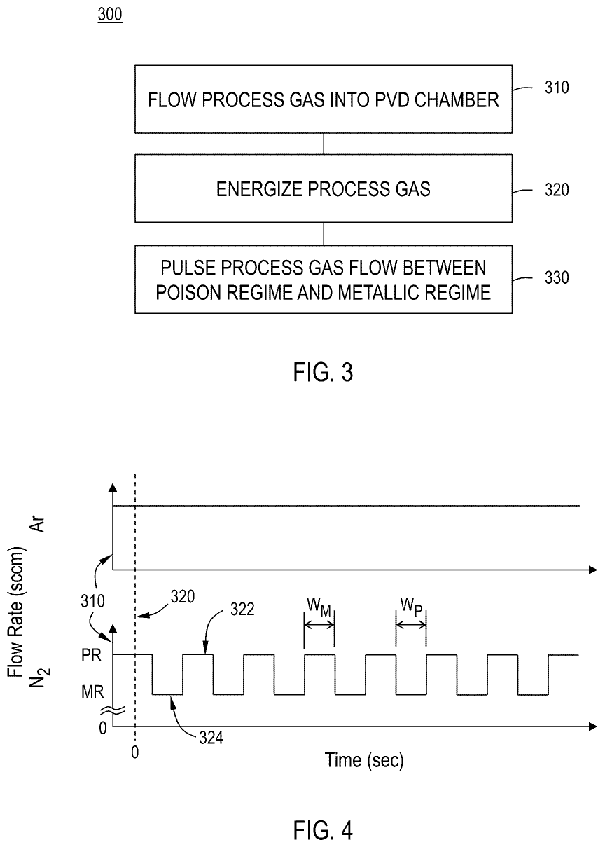

Accordingly, with reference to FIGS. 3 and 4, one or more embodiment of the disclosure are directed to methods 300 of forming a work function layer for a transistor. FIG. 3 illustrates a flowchart of the method 300. FIG. 4 shows a graph of the flow rates of the process gases during the method 300.

At operation 310 of method 300, a process gas is flowed into the inner volume 108 of a physical vapor deposition (PVD) processing chamber 100. The PVD chamber has a substrate 104 with a substrate surface 105 positioned therein, and a sputtering target 140. Substrate 104 (also referred to as a wafer) can be any suitable substrate material known to the skilled artisan. The sputtering target 140 can be any suitable material known to the skilled artisan that can be used to form a work function layer. In some embodiments, the sputtering plate 141 of the sputtering target 140 comprises or consists essentially of one or more of ruthenium (Ru), copper (Cu), cobalt (cobalt), molybdenum (Mo), tantalum (Ta), tungsten (W), or titanium (Ti). In some embodiments, the sputtering target 140 comprises or consists essentially of titanium. The skilled artisan will recognize that the use of sputtering target in this manner, refers to the sputtering plate 141 of the sputtering target 140 and does not imply that the entire sputtering target 140 including the backing plate 142 is made of the stated material. The use of the term “consists essentially of” in this manner means that the composition of the sputtering plate is greater than or equal to 95%, 98%, 99% or 99.5% of the stated material on an atomic basis. In some embodiments, the sputtering target comprises or consists essentially of titanium nitride (TiN).

At operation 320, indicated by the dotted line in FIG. 4, the process gas disposed in the inner volume 108 of the processing chamber is energized to create a plasma within the inner volume 108. The processing chamber 100 has a sputtering target 140 and the plasma causes atoms to be ejected from the sputtering target 140 toward a substrate surface 105. Energizing the plasma at operation 320 is the zero time or start time of the pulsing portion of the method 300.

At operation 320 of method 300, the process gas is pulsed between a poison regime 322 and a metallic regime 324 using a fast response mass flow controller 166 to deposit the work function layer. As used in this specification and the appended claims, a “fast response mass flow controller” has an ON response delay and an OFF response delay that are independently less than or equal to 0.25 seconds at a flow rate in the range of 5 sccm to 100 sccm. A response delay is defined as the time between sending a signal to the mass flow controller to change flow rate to the actual time that the flow rate has been changed.

The poison regime (PR) 322 is defined as the pulse period with a lower flow rate of the process gas than at the metallic regime (MR) 324. For example, if the process gas comprises or consists essentially of nitrogen (N₂), the flow rate of the nitrogen is higher during the poison regime pulse than during the metallic regime pulse. As used in this manner, the term “consists essentially of” means that the composition of the process gas is greater than or equal to 95%, 98% or 99% of the stated species. In some embodiments, there is a flow of the process gas throughout the method 300 with no pulse periods without the reactive portion of the process gas. For example, in some embodiments, as shown in FIG. 4, the process gas comprises a constant flow of argon (Ar) and a pulsed flow of nitrogen (N₂). In this case, nitrogen is the reactive species because it will be incorporated into the work function layer, while the argon is part of the make-up gas and is energized to the plasma.

The metallic regime (MR) 324 of some embodiments has a flow rate in the range of 10 sccm to 50 sccm, or in the range of 15 sccm to 40 sccm, or in the range of 20 sccm to 30 sccm. The flow rates of the poison regime and the metallic regime refer to the flow rate of the reactive species ignoring the flow rate of the make-up gas which is often much greater. The skilled artisan will recognize that the flow rates provided herein are for the species that will be incorporated into the work function layer and are not specified for the plasma or make-up gas. In some embodiments, the flow rate of the reactive species (e.g., nitrogen (N₂)) during the metallic regime (MR) 324 is greater than or equal to 5 sccm and less than or equal to 100 sccm, 90 sccm, 80 sccm, 70 sccm, 60 sccm, 50 sccm, 40 sccm or 30 sccm. In some embodiments, the flow rate of the reactive species during the metallic regime (MR) 324 is greater than or equal to 5 sccm, 10 sccm, 15 sccm, 20 sccm or 25 sccm and is less than or equal to 50 sccm.

The poison regime (PR) 322 of some embodiments has a flow rate of the reactive species in the range of 15 sccm to 65 sccm, or in the range of 20 sccm to 50 sccm, or in the range of 25 sccm to 35 sccm. In some embodiments, the flow rate of the reactive species during the poison regime (PR) 322 is greater than or equal to 8 sccm, 10 sccm, 15 sccm, 20 sccm, 23 sccm, 25 sccm, 28 sccm, 30 sccm, 35 sccm, 40 sccm, 50 sccm, 60 sccm, 70 sccm, 80 sccm, 90 sccm, 100 sccm or 110 sccm. In some embodiments, the reactive species during the poison regime (PR) 322 is greater than or equal to 8 sccm and less than or equal to 110 sccm, 100 sccm, 90 sccm, 80 sccm, 70 sccm, 60 sccm, 50 sccm, 40 sccm, 35 sccm, 30 sccm or 28 sccm.

The flow rate of the reactive species during the metallic regime (MR) 324 is less than the flow rate of the reactive species during the poison regime (PR) 322. In some embodiments, the metallic regime flow rate is greater than or equal to 2 sccm, 3 sccm, 4 sccm, 5 sccm, 6 sccm, 7 sccm, 8 sccm, 9 sccm or 10 sccm lower than the poison regime flow rate. In some embodiments, the poison regime flow rate is 28 sccm and the metallic regime flow rate is 25 sccm.

The pulse width of the poison regime and the metallic regime can be controlled to form the work function layer. However, it was surprisingly found that increasing the pulse width of the conventional (non-fast response) MFC had no impact on the center-to-edge N/Ti ratio in a titanium nitride work function layer. The inventors have surprisingly found that the use of a fast response MFC allow for shorter pulse widths which also may affect the work function layer center-to-edge atomic ratios.

In some embodiments, the poison regime 322 pulse has a duration in the range of 50 msec to 500 msec. In some embodiments, the metallic regime 324 pulse has a duration in the range of 50 msec to 500 msec. In some embodiments, the poison regime 322 pulse and the metallic regime 324 pulse are independently in the range of 50 msec to 500 msec, or in the range of 60 msec to 300 msec, or in the range of 70 msec to 150 msec, or in the range of 75 msec to 125 msec. In some embodiments, the poison regime 322 pulse and the metallic regime 324 pulse have substantially the same durations in the range of 50 msec to 500 msec, or in the range of 60 msec to 300 msec, or in the range of 70 msec to 150 msec, or in the range of 75 msec to 125 msec. As used in this manner, the term “substantially the same” means the average pulse widths during the poison regime and the metallic regime are within +10% relative to the longer average pulse width.

In some embodiments, the poison regime reduces nitrogen incorporated into the work function layer at an edge of the wafer (or substrate), relative to the metallic regime. In some embodiments, the pulse width of the poison regime or metallic regime, relative to the other regime, is controlled to increase or decrease the nitrogen composition of the work function layer at the edge of the wafer. In some embodiments, the center-to-edge uniformity of the work function layer on the substrate surface is greater than a center-to-edge uniformity of a work function layer deposited without pulsing between the poison regime and the metallic regime. In some embodiments, in which a titanium nitride work function layer is formed, a N/Ti ratio center-to-edge difference for the work function layer is less than or equal to 0.025 absolute, or less than or equal to 0.02 absolute, or less than or equal to 0.015 absolute. The center-to-edge difference is measured as the average ratio within the region of the center or the region of the edge of the wafer. In some embodiments in which a titanium nitride work function layer is formed, a N/Ti ratio of the work function layer is in the range of 0.95 to 1.05, or in the range of 0.96 to 1.04, or in the range of 0.97 to 1.03, or in the range of 0.98 to 1.02, or in the range of 0.99 to 1.01, or about 1. The inventors have surprisingly found that a lower nitrogen flow rate during the metallic regime, relative to the poison regime, results in a lower nitrogen content in the titanium nitride film, but still produces a film with an overall N/Ti ratio close to 1.

In some embodiments, the substrate is moved from a first chamber to a separate, next chamber for further processing. The substrate can be moved directly from the first chamber to the separate processing chamber, or the substrate can be moved from the first chamber to one or more transfer chambers, and then moved to the separate processing chamber. Accordingly, the processing apparatus may comprise multiple chambers in communication with a transfer station. An apparatus of this sort may be referred to as a “cluster tool” or “clustered system”, and the like.

Generally, a cluster tool is a modular system comprising multiple chambers which perform various functions including substrate center-finding and orientation, degassing, annealing, deposition and/or etching. According to one or more embodiments, a cluster tool includes at least a first chamber and a central transfer chamber. The central transfer chamber may house a robot that can shuttle substrates between and among processing chambers and load lock chambers. The transfer chamber is typically maintained at a vacuum condition and provides an intermediate stage for shuttling substrates from one chamber to another and/or to a load lock chamber positioned at a front end of the cluster tool. However, the exact arrangement and combination of chambers may be altered for purposes of performing specific steps of a process as described herein.

Other processing chambers which may be used include, but are not limited to, cyclic deposition including a deposition step, and an annealing or treatment step, atomic layer deposition (ALD), chemical vapor deposition (CVD), physical vapor deposition (PVD), etch, pre-clean, chemical clean, plasma nitridation, degas, orientation, hydroxylation and other substrate processes. By carrying out processes in a chamber on a cluster tool, surface contamination of the substrate with atmospheric impurities can be avoided without oxidation prior to depositing a subsequent film.

According to one or more embodiments, the substrate is continuously under vacuum or “load lock” conditions and is not exposed to ambient air when being moved from one chamber to the next. The transfer chambers are thus under vacuum and are “pumped down” under vacuum pressure. Inert gases may be present in the processing chambers or the transfer chambers. In some embodiments, an inert gas is used as a purge gas to remove some or all of the reactants (e.g., reactant). According to one or more embodiments, a purge gas is injected at the exit of the deposition chamber to prevent reactants (e.g., reactant) from moving from the deposition chamber to the transfer chamber and/or additional processing chamber. Thus, the flow of inert gas forms a curtain at the exit of the chamber.

The substrate can be processed in single substrate deposition chambers, where a single substrate is loaded, processed and unloaded before another substrate is processed. The substrate can also be processed in a continuous manner, similar to a conveyer system, in which multiple substrates are individually loaded into a first part of the chamber, move through the chamber and are unloaded from a second part of the chamber. The shape of the chamber and associated conveyer system can form a straight path or curved path. Additionally, the processing chamber may be a carousel in which multiple substrates are moved about a central axis and are exposed to deposition, etch, annealing, cleaning, etc., processes throughout the carousel path.

The substrate can also be stationary or rotated during processing. A rotating substrate can be rotated (about the substrate axis) continuously or in discrete steps. For example, a substrate may be rotated throughout the entire process, or the substrate can be rotated by a small amount between exposures to different reactive or purge gases. Rotating the substrate during processing (either continuously or in steps) may help produce a more uniform deposition or etch by minimizing the effect of, for example, local variability in gas flow geometries.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

What is claimed is:

1. A method of forming a work function layer for a transistor, the method comprising:
energizing a process gas disposed in an inner volume of a processing chamber to create a plasma, the processing chamber having a sputtering target and the plasma causing atoms to eject from the sputtering target toward a substrate surface; and
pulsing the process gas between a poison regime and a metallic regime using a fast response mass flow controller to deposit the work function layer on the substrate surface, the fast response mass flow controller having an ON response delay and an OFF response delay independently less than or equal to 0.25 seconds at a flow rate in the range of 5 sccm to 100 sccm.

2. The method of claim 1, wherein the sputtering target comprises titanium.

3. The method of claim 1, wherein the sputtering target comprises titanium nitride.

4. The method of claim 1, wherein the process gas comprises nitrogen (N₂).

5. The method of claim 4, wherein the process gas further comprises argon.

6. The method of claim 5, wherein the argon is flowed at a constant rate and the nitrogen is pulsed.

7. The method of claim 4, wherein the metallic regime comprises a nitrogen flow rate in the range of 20 sccm to 30 sccm.

8. The method of claim 7, wherein the poison regime comprises a nitrogen flow rate in the range of 25 sccm to 35 sccm, and the metallic regime flow rate is less than the poison regime flow rate.

9. The method of claim 8, wherein the poison regime flow rate is greater than or equal to 2 sccm higher than the metallic regime flow rate.

10. The method of claim 8, wherein the poison regime pulse has a duration in the range of 50 msec to 500 msec.

11. The method of claim 8, wherein the metallic regime pulse has a duration in the range of 50 msec to 500 msec.

12. The method of claim 8, wherein the poison regime pulse and the metallic regime pulse have substantially the same durations in the range of 75 msec to 125 msec.

13. The method of claim 8, wherein the metallic regime reduces nitrogen incorporated into the work function layer at an edge of the wafer, relative to the poison regime.

14. The method of claim 8, wherein a center-to-edge uniformity of the work function layer on the substrate surface is greater than a center-to-edge uniformity of a work function layer deposited without pulsing between the poison regime and the metallic regime.

15. The method of claim 14, wherein a N/Ti ratio center-to-edge difference for the work function layer is less than or equal to 0.025 absolute.

16. The method of claim 14, wherein a N/Ti ratio of the work function layer is in the range of 0.95 to 1.05.

17. A method of forming a titanium nitride work function layer for a transistor, the method comprising:
flowing a process gas comprising argon and nitrogen into an inner volume of a processing chamber comprising a titanium target and a substrate with a substrate surface;
energizing the process gas to create a plasma in the inner volume to cause titanium atoms to eject from the sputtering target toward the substrate surface; and
pulsing the process gas between a poison regime and a metallic regime using a fast response mass flow controller to deposit the titanium nitride work function layer on the substrate surface,
wherein the fast response mass flow controller having an ON response delay and an OFF response delay independently less than or equal to 0.15 seconds at a flow rate in the range of 5 sccm to 100 sccm,
wherein the metallic regime has a nitrogen flow rate in the range of 20 sccm to 30 sccm, and the poison regime has a nitrogen flow rate in the range of 25 sccm to 35 sccm and is greater than the nitrogen flow rate of the metallic regime.

18. The method of claim 17, wherein the poison regime pulse and the metallic regime pulse have substantially the same durations in the range of 75 msec to 125 msec.

19. The method of claim 17, wherein the argon flowed of the process gas is maintained at a constant rate while the nitrogen flow is pulsed.

20. The method of claim 17, wherein a center-to-edge uniformity of the titanium nitride work function layer on the substrate surface is greater than a center-to-edge uniformity of a titanium nitride function layer deposited without pulsing the nitrogen flow between the poison regime and the metallic regime.
